(19) United States
(12) Patent Application Publication
(10) Pub. No.: US 2025/0033161 A1
(43) Pub. Date: Jan. 30, 2025

(54) POLISHING PAD FORMED FROM DUAL CURATIVE

(71) Applicant: DuPont Electronic Materials Holding, Inc., Newark, DE (US)

(72) Inventor: Fengji Yeh, Wilmington, DE (US)

(21) Appl. No.: 18/360,947

(22) Filed: Jul. 28, 2023

(51) Int. Cl. B24B 37/24; B24B 37/22

(52) U.S. Cl. CPC B24B 37/24; B24B 37/22

(57) ABSTRACT

A chemical mechanical polishing pad comprising a polishing layer which comprises a reaction product of an isocyanate terminated urethane prepolymer; and a curative system comprising a sulfur containing diamine curative, and a high molecular weight polyol curative, wherein the high molecular weight polyol curative can have reduced polishing defects. The high molecular weight polyol curative has a number average molecular weight of 2,500 to 100,000; and an average of 3 to 10 hydroxyl groups per molecule. The weight ratio of the high molecular weight polyol curative to the sulfur containing diamine curative is in the range of 3:10 to 7:10.

### FIELD OF THE INVENTION

This invention relates to polishing pads useful in chemical mechanical polishing.

### BACKGROUND OF THE INVENTION

In the fabrication of integrated circuits and other electronic devices, multiple layers of conducting, semiconducting and dielectric materials are deposited onto and removed from a surface of a semiconductor wafer. Thin layers of conducting, semiconducting and dielectric materials may be deposited using a number of deposition techniques. Common deposition techniques in modern wafer processing include physical vapor deposition (PVD), also known as sputtering, chemical vapor deposition (CVD), plasma-enhanced chemical vapor deposition (PECVD) and electrochemical plating, among others. Common removal techniques include wet and dry isotropic and anisotropic etching, among others.

As layers of materials are sequentially deposited and removed, the uppermost surface of the wafer becomes non-planar. Because subsequent semiconductor processing (e.g., metallization) requires the wafer to have a flat surface, the wafer needs to be planarized. Planarization is useful for removing undesired surface topography and surface defects, such as rough surfaces, agglomerated materials, crystal lattice damage, scratches and contaminated layers or materials.

Chemical mechanical planarization, or chemical mechanical polishing (CMP), is a common technique used to planarize or polish work pieces such as semiconductor wafers. In conventional CMP, a wafer carrier, or polishing head, is mounted on a carrier assembly. The polishing head holds the wafer and positions the wafer in contact with a polishing layer of a polishing pad that is mounted on a table or platen within a CMP apparatus. The carrier assembly provides a controllable pressure between the wafer and polishing pad. Simultaneously, a polishing medium (e.g., slurry) is dispensed onto the polishing pad and is drawn into the gap between the wafer and polishing layer. To effect polishing, the polishing pad and wafer typically rotate relative to one another. As the polishing pad rotates beneath the wafer, the wafer sweeps out a typically annular polishing track, or polishing region, wherein the wafer's surface directly confronts the polishing layer. The wafer surface is polished and made planar by chemical and mechanical action of the polishing layer and polishing medium on the surface.

Defects, such as scratches and chatter marks, can be formed in substrate being polished during the polishing process.

It would be desirable to have a pad that reduces polishing defects while maintaining or improving other important properties such as removal rate.

### SUMMARY OF THE INVENTION

Disclosed herein is a chemical mechanical polishing pad comprising a polishing layer having a polishing surface, wherein the polishing layer comprises a reaction product of an isocyanate terminated urethane prepolymer; and a curative system comprising a sulfur containing diamine curative, and a high molecular weight polyol curative, wherein the high molecular weight polyol curative has a number average molecular weight, Mn, of 2,500 to 100,000; and wherein the high molecular weight polyol curative has an average of 3 to 10 hydroxyl groups per molecule; wherein the weight ratio of the high molecular weight polyol curative to the sulfur containing diamine curative is in the range of 3:10 to 7:10.

### DETAILED DESCRIPTION OF THE INVENTION

### Isocyanate Terminated Urethane Prepolymer

The isocyanate terminated urethane prepolymer used in the formation of the polishing layer of the chemical mechanical polishing pad of the present invention can comprise a reaction product of ingredients, comprising: a polyfunctional isocyanate and a prepolymer polyol.

The polyfunctional isocyanate can be selected from the group consisting of an aliphatic polyfunctional isocyanate, an aromatic polyfunctional isocyanate and a mixture thereof. The polyfunctional isocyanate can be a diisocyanate selected from the group consisting of 2,4 toluene diisocyanate; 2,6 toluene diisocyanate; 2,2′ diphenylmethane diisocyanate; 2,4′ diphenylmethane diisocyanate; 4,4′ diphenylmethane diisocyanate; naphthalene 1,5 diisocyanate; tolidine diisocyanate; para phenylene diisocyanate; xylylene diisocyanate; isophorone diisocyanate; hexamethylene diisocyanate; 4,4′ dicyclohexylmethane diisocyanate; cyclohexane diisocyanate; and mixtures thereof.

The prepolymer polyol can be selected from the group consisting of diols, polyols, polyol diols, copolymers thereof, and mixtures thereof. The prepolymer polyol can be selected from the group consisting of polyether polyols (e.g., poly(oxytetramethylene)glycol, poly(oxypropylene)glycol, poly(oxyethylene)glycol, poly(oxypropylene)-co-poly(oxyethylene) glycol); polycarbonate polyols; polyester polyols; polycaprolactone polyols; mixtures thereof; and, mixtures thereof with one or more low molecular weight polyols selected from the group consisting of ethylene glycol; 1,2 propylene glycol; 1,3 propylene glycol; 1,2 butanediol; 1,3 butanediol; 2 methyl 1,3 propanediol; 1,4 butanediol; neopentyl glycol; 1,5 pentanediol; 3 methyl 1,5 pentanediol; 1,6 hexanediol; diethylene glycol; dipropylene glycol; and, tripropylene glycol. For example, the prepolymer polyol can be selected from the group consisting of at least one of polytetramethylene ether glycol (PTMEG); polypropylene ether glycols (PPG), polyethylene ether glycols (PEG), and polyethylene ether glycol-co-polypropylene ether glycols (PEG-PPG copolymer); optionally, mixed with at least one low molecular weight polyol selected from the group consisting of ethylene glycol; 1,2 propylene glycol; 1,3 propylene glycol; 1,2 butanediol; 1,3 butanediol; 2 methyl 1,3 propanediol; 1,4 butanediol; neopentyl glycol; 1,5 pentanediol; 3 methyl 1,5 pentanediol; 1,6 hexanediol; diethylene glycol; dipropylene glycol; and, tripropylene glycol. The prepolymer polyol can be primarily (i.e., ≥90 wt %) PTMEG.

The isocyanate terminated urethane prepolymer can have an unreacted isocyanate (NCO) concentration of 7 to 11.4, 8 to 10, 8.3 to 9.8, 8.5 to 9.5, 8.6 to 9.3, 8.7 to 9.25, or 8.9 to 9.25 wt % based on total weight of the isocyanate terminated urethane prepolymer. Examples of commercially available isocyanate terminated urethane prepolymers include Imuthane® prepolymers (available from COIM USA, Inc., such as, PET 80A, PET 85A, PET 90A, PET 93A, PET 95A, PET 60D, PET 70D, PET 75D); Adiprene® prepolymers (available from LANXESS Urethane Systems, such as, LF 800A, LF 900A, LF 910A, LF 930A, LF 931A, LF 939A, LF 950A, LF 952A, LF 600D, LF 601D, LF 650D, LF 667, LF 700D, LF750D, LF751D, LF752D, LF753D and L325); Andur® prepolymers (available from Anderson Development Company, such as, 70APLF, 80APLF, 85APLF, 90APLF, 95APLF, 60DPLF, 70APLF, 75APLF).

The isocyanate terminated urethane prepolymer can be a low free isocyanate terminated urethane prepolymer having less than 0.1 wt % free toluene diisocyanate (TDI) monomer content.

### Curative

The curative comprises a sulfur containing diamine curative and a high molecular weight polyol curative.

The sulfur-containing diamine curative can comprise a diamine functional aromatic compound having one or more alkylthio group pendant from an aromatic ring. For example, the sulfur-containing diamine curative can comprise, consist essentially of, or consist of dialkylthiotoluenediamine, monoalkylthiotoluenediamine, or both, in each case where the alkyl group comprises 1, 2, or 3 carbon atoms. For example, the sulfur curative can comprise, consist essentially of, or consist of Monomethylthiotoluenediamine, dimethylthiotoluenediamine, or combinations thereof. For example, the sulfur curative can comprise 95 to 97 weight percent dimethylthiotoluenediamine based on total weight of the sulfur-containing diamine curative. For example, the sulfur curative can comprise 2 to 3% Monomethylthiotoluenediamine based on total weight of the sulfur-containing diamine curative. For example, the sulfur-containing diamine curative can comprise 3,5-dimethylthio-2,4-toluenediamine, isomers of 3,5-dimethylthio-2,4-toluenediamine (e.g., 3,5-dimethylthio-2,6-toluenediamine), or a combination thereof.

The high molecular weight polyol curative can have a number average molecular weight, Mn, of 2,500 to 100,000 g. For example, the high molecular weight polyol curative used can have a number average molecular weight, Mn, of 5,000 to 50,000, 7,500 to 25,000; or 10,000 to 12,000. Number average molecular weight can be determined by gel permeation chromatography against a polystyrene reference.

The high molecular weight polyol curative can have an average of three to ten, four to eight, five to seven, or six hydroxyl groups per molecule.

Examples of commercially available high molecular weight polyol curatives include Specflex® polyols, Voranol® polyols and Voralux® polyols (available from The Dow Chemical Company); Multranol® Specialty Polyols and Ultracel® Flexible Polyols (available from Covestro AG); and Pluracol® Polyols (available from BASF).

The present inventors discovered that use of the combination of the sulfur containing diamine curative with the high molecular weight polyol curative in forming a polishing pad provided a surprising reduction in defects during polishing compared to use of either of those curatives alone or compared to the high molecular weight polyol in combination with a non-sulfur containing curative such as 4,4′ methylene bis (2 chloroaniline) (MBOCA).

### Stoichiometry of Reactive Groups

The sum of the reactive hydrogen groups (i.e., the sum of the amine (NH2) groups and the hydroxyl (OH) groups) contained in the components of the curative system (i.e., the high molecular weight polyol curative and the difunctional curative) divided by the unreacted isocyanate (NCO) groups in the isocyanate terminated urethane prepolymer (i.e., the stoichiometric ratio) used in the formation of the polishing layer of the chemical mechanical polishing pad of the present invention can be from 0.85 up to 1.15, up to 1.05, or up to 1.0.

### Pad Structure and Configuration

The polishing surface of the polishing layer of the chemical mechanical polishing pad of the present invention is adapted for polishing a substrate. For example, the polishing surface can be adapted for polishing a substrate selected from at least one of a magnetic substrate, an optical substrate and a semiconductor substrate. Preferably, the polishing surface is adapted for polishing a semiconductor substrate. For example, the polishing surface can be adapted for polishing a silicon oxide (e.g., tetraethyl orthosilicate (TEOS)) surface or a silicon nitride (SiN) surface of a semiconductor substrate.

The polishing surface can have macrotexture selected from at least one of perforations and grooves. Perforations can extend from the polishing surface part way or all the way through the thickness of the polishing layer. The grooves can be arranged on the polishing surface such that upon rotation of the chemical mechanical polishing pad during polishing, at least one groove sweeps over the surface of the substrate being polished. For example, the polishing surface can have macrotexture including at least one groove selected from the group consisting of curved grooves, linear grooves and combinations thereof.

For example, the groove design can be selected from the group consisting of concentric grooves (which may be circular or spiral), curved grooves, radial grooves, cross hatch grooves (e.g., arranged as an X Y grid across the pad surface), other regular designs (e.g., hexagons, triangles), tire tread type patterns, irregular designs (e.g., fractal patterns), and combinations thereof. For example, the groove design can be selected from the group consisting of random grooves, concentric grooves, spiral grooves, radial grooves, cross hatched grooves, X Y grid grooves, hexagonal grooves, triangular grooves, fractal grooves and combinations thereof. As a specific example, the polishing surface can have a concentric groove pattern or a combination of a concentric groove pattern with radial grooves formed therein. The groove profile can be selected from rectangular with straight side walls or the groove cross section may be “V” shaped, “U” shaped, saw tooth, and combinations thereof.

The polishing layer of the chemical mechanical polishing pad of the present invention optionally further comprises a plurality of microelements. The plurality of microelements can be uniformly dispersed throughout the polishing layer. The plurality of microelements can be selected from entrapped gas bubbles, hollow core polymeric materials, liquid filled hollow core polymeric materials, water soluble materials and an insoluble phase material (e.g., mineral oil). The plurality of microelements has a volume average diameter of less than 150 μm (more preferably of less than 50 μm; most preferably of 10 to 50 μm). The plurality of microelements comprise polymeric microballoons. The microballoons can have shell walls comprising, for example, polyacrylonitrile or a polyacrylonitrile copolymer (e.g., Expancel® microspheres from Nouryon). The plurality of microelements are incorporated into the polishing layer to provide 0 to 50, 5 to 35, or 10 to 25 volume % porosity.

The polishing layer of the chemical mechanical polishing pad of the present invention can be provided in both porous and nonporous (i.e., unfilled) configurations. The polishing layer of the chemical mechanical polishing pad of the present invention exhibits a density of ≥0.6 g/cm³—for example, 0.7 to 1.2, 0.75 to 1.0, or 0.75 to 0.95 g/cm³ as measured according to ASTM D1622.

The polishing layer of the chemical mechanical polishing pad of the present invention can have a Shore D hardness of 40 to 70, 45 to 55, or 50 to 55, as measured according to ASTM D2240. These hardness were measured by stacking four 3.81 cm square samples having a thickness of 80 mils (2.032 mm) to eliminate error from measuring the support surface using a Hoto Instruments Asker P2 Durometer with a D probe.

The polishing layer of the chemical mechanical polishing pad of the present invention exhibits an elongation to break of 125 to 350, 140 to 300, or 150 to 200% as measured according to Test Method A in ASTM D412-98a (Reapproved 2002). The test used an MTS Criterion C43 tester with an Instron 2712-02 load cell of a maximum load at 1000 Newton and Instron pneumatic side action grips clamping at approximately 30 psi (207 kPa). The test specimens were based on the dimension of Standard Dumbbell Die C with US customary units with a thickness of 80 mils (2.032 mm) and the test temperature was at 23° C.+/−2° C. The specimens were deformed at 20 inches (50.8 cm)+/−2 inches per minute (5.08 cm/min) of the grips. Five replicates were measured for each sample and the median values were reported.

The polishing layer of the chemical mechanical polishing pad of the present invention can have a shear modulus (at 30° C.), G′30, of 50 to 300, 75 to 250, or 100 to 200 MPa as measured according to ASTM D5279-13 with a sample size of 20.00 mm×6.53 mm×2.02 mm. The temperature ramp rate is set at 3° C./min with a dynamic-torsional displacement at 0.2% and a frequency of 10.0 rad/sec using a TA Instruments ARES-G2 Torsional Rheometer and a torsion rectangular sample clamp.

The polishing layer of the chemical mechanical polishing pad of the present invention can have a shear modulus (at 40° C.), G′40, of 45 to 275 MPa as measured according to ASTM D5279-13.

The polishing layer of the chemical mechanical polishing pad of the present invention can have a shear loss modulus (at 40° C.), G″40, of 3 to 20 MPa as measured according to ASTM D5279-13.

The polishing layer of the chemical mechanical polishing pad of the present invention can have a G′ 30/90 ratio of from 1.5 or from 2 up to 4 as measured according to ASTM D5279-13.

The polishing layer of the chemical mechanical polishing pad of the present invention can have a toughness of from 20 or from 25 up to 80, up to 70, up to 60, up to 50, or up to 40 MPa was calculated from stress-strain curves measured according to Test Method A in ASTM D412-98a (Reapproved 2002) as described above.

The polishing layer of the chemical mechanical polishing pad of the present invention can have a tensile strength of from 10 or from 15 up to 35, up to 30, or up to 25 MPa as measured according to Test Method A in ASTM D412-98a (Reapproved 2002) as described above.

Polishing layer materials exhibiting high elongation to break values tend to reversibly deform when subjected to machining operations, which results in groove formation that is unacceptably poor and texture creation during diamond conditioning that is insufficient. The unique curative system used in the formation of the polishing layer of the chemical mechanical polishing pad of the present invention provides both Shore D hardness of 40 to 70, 45 to 55, or 50 to 55 coupled with an elongation to break of 125 to 300, 140 to 300, 150 to 250, or 150 to 200% as measured according to Test Method A in ASTM D412-98a (Reapproved 2002) as described above.

The polishing layer can have an average thickness of 20 to 150 mils, 30 to 125 mils, 40 to 120 mils, or 50 to 100 mils (0.5 to 3.8 mm, 0.8 to 3.2 mm, 1.0 to 3.0 mm or 1.3 to 2.5 mm.

The chemical mechanical polishing pad of the present invention can be adapted to be interfaced with a platen of a polishing machine. For example, the chemical mechanical polishing pad can be adapted to be affixed to the platen of a polishing machine. For example, the affixing can occur using at least one of a pressure sensitive adhesive and vacuum.

The chemical mechanical polishing pad of the present invention optionally further comprises at least one additional layer interfaced with the polishing layer. For example, the chemical mechanical polishing pad optionally further comprises a compressible base layer adhered to the polishing layer. The compressible base layer can improve conformance of the polishing layer to the surface of the substrate being polished.

An important step in substrate polishing operations is determining an endpoint to the process. One popular in situ method for endpoint detection involves providing a polishing pad with a window or a plurality of windows, which is transparent to select wavelengths of light. During polishing, a light beam is directed through the window to the substrate surface, where it reflects and passes back through the window to a detector (e.g., a spectrophotometer). Based on the return signal, properties of the substrate surface (e.g., the thickness of films thereon) can be determined for endpoint detection purposes. To facilitate such light based endpoint methods, the chemical mechanical polishing pad of the present invention, optionally further comprises an endpoint detection window. The endpoint detection window can be selected from an integral window incorporated into the polishing layer; and a plug in place endpoint detection window block incorporated into the chemical mechanical polishing pad. One of ordinary skill in the art will know to select an appropriate material of construction for the endpoint detection window for use in the intended polishing process.

### Method of Making a Pad

A method of making a chemical mechanical polishing pad of the present invention, can comprise combining the isocyanate terminated urethane prepolymer and the curative system to form a combination; allowing the combination to react to form a product; forming a polishing layer from the product; and forming the chemical mechanical polishing pad with the polishing layer. The combination of isocyanate terminated urethane prepolymer and the curative system can further comprise microelements, for example, expandable polymeric microballoons.

The method can comprise providing a mold; pouring the combination into the mold; and, allowing the combination to react in the mold to form a cured cake inside a heated oven; wherein the polishing layer is derived from the cured cake. For example, the cured cake is skived (sliced or cut) to derive multiple polishing layers from a single cured cake. Optionally, the method further comprises heating the cured cake to facilitate the skiving operation. Optionally, the cured cake can be heated using infrared heating lamps during the skiving operation in which the cured cake is skived into a plurality of polishing layers.

The method of making the chemical mechanical polishing pad of the present invention, optionally, further comprises: providing at least one additional layer (e.g., a base layer or sub-pad layer); and, interfacing the at least one additional layer with the polishing layer to form the chemical mechanical polishing pad. The at least one additional layer can be affixed with the polishing layer by known techniques, such as, by using an adhesive (e.g., a pressure sensitive adhesive, a hot melt adhesive, a contact adhesive).

The method of making the chemical mechanical polishing pad of the present invention, optionally, further comprises: providing an endpoint detection window; and incorporating the endpoint detection window into the chemical mechanical polishing pad.

### Method of Polishing

The method of the present invention for chemical mechanical polishing of a substrate preferably comprises: providing a chemical mechanical polishing apparatus having a platen; providing at least one substrate to be polished (for example, wherein the substrate is selected from the group consisting of at least one of a magnetic substrate, an optical substrate and a semiconductor substrate; preferably, wherein the substrate is a semiconductor substrate); providing a chemical mechanical polishing pad of the present invention; installing onto the platen the chemical mechanical polishing pad; optionally, providing a polishing medium (e.g., polishing slurry or a non-abrasive containing reactive liquid formulation) at an interface between a polishing surface of the chemical mechanical polishing pad and the substrate; creating dynamic contact between the polishing surface and the substrate, wherein at least some material is removed from the substrate; and, optionally, conditioning of the polishing surface with an abrasive conditioner. The polishing slurry can comprise, for example, cerium oxide abrasive with or without chemical additives. Optionally, in the method of the present invention, the chemical mechanical polishing apparatus provided further includes a light source and a photosensor (preferably a multisensor spectrograph); and, the chemical mechanical polishing pad provided further includes an endpoint detection window; and, the method further comprises: determining a polishing endpoint by transmitting light from the light source through the endpoint detection window and analyzing the light reflected off the surface of the substrate back through the endpoint detection window incident upon the photosensor.

### EXAMPLES

### Forming the Polishing Layer

An isocyanate terminated urethane prepolymer was mixed with a curative system and expandable polymeric microspheres according to the formulations as shown in Table 1. For each formulation the isocyanate terminated urethane prepolymer has an NCO % of about 9.1%. The sulfur containing curative, labeled SC1, comprises 95-98 weight percent dimethylthiotoluenediamine and 2-3 weight percent monomethylthiotoluenediamine. The high molecular weight polyol curative, labeled HMWC2, has an average molecular weight of about 11,400 grams/mole and a nominal functionality of OH groups of 6. The expandable polymeric microsphere was added to the mixture in an amount to obtain the specific gravity as stated in Table 1. The amounts of isocyanate terminated urethane prepolymer and curative system is selected to provide the stoichiometric ratio of the reactive hydrogen groups in the curative system to unreacted NCO groups in the isocyanate terminated urethane prepolymer as shown in the Table. The mixture is fed to a mold and heated to form a cured composition. The density or specific gravity is determined by the actual weight and volume of the skived pad using the polymer density. The cured composition is formed into a thickness for use as a polishing layer and applied to a subpad.

TABLE 1

| | Prepolymer | | Curative-1 | | Curative-2 | | |
|---|---|---|---|---|---|---|---|
| | Amount | | Amount | | Amount | | |
| | (parts by | | (parts by | | (parts by | | |
| Example | weight) | Curative-1 | weight) | Curative-2 | weight) | Stoichiometry | Pad SG |
| C-1 | 100 | MBOCA | 25.1 | — | — | 0.87 | 0.80 |
| C-2 | 100 | MBOCA | 30.4 | — | — | 1.05 | 0.79 |
| C-3 | 100 | SC1 | 23.2 | — | — | 1.00 | 0.80 |
| C-4 | 100 | MBOCA | 29.1 | HMWC2 | 17.7 | 1.05 | 0.81 |
| I-1 | 100 | SC1 | 23.8 | HMWC2 | 10.3 | 1.05 | 0.77 |
| I-2 | 100 | SC1 | 23.6 | HMWC2 | 14.4 | 1.05 | 0.77 |
| I-3 | 100 | SC1 | 20.8 | HMWC2 | 9.05 | 0.92 | 0.78 |
| I-4 | 100 | SC1 | 23.8 | HMWC2 | 10.3 | 1.05 | 0.99 |

### Testing the Pads Having the Polishing Layer for Defects.

Pads were made with polishing layers of the formulations as set out in Table 1. These were used to polish 3 wafers with a ceria slurry.

A first set of wafers polished with pads having polishing layers of the formulation set out in Table 2 wafers were examined for scratch and chatter mark defects by Scanning Electronic Microscopy. The data normalized to the pads comprising the formulation of Comparative 1 are found in Table 2 shows a significant improvement in defect for the inventive formulation.

A second set of wafers polished with pads having polishing layers of the formulation set out in Table 3 wafers were examined for scratch and chatter mark defects by Scanning Electronic Microscopy and for Removal rates of TEOS and SiN. The data normalized to the pads comprising the formulation of Comparative 1 are found in Table 3 shows a significant improvement in defect for the inventive formulations and an improvement in SiN Removal Rates.

A third set of wafers polished with pads having polishing layers of the formulation set out in Table 4 wafers were examined for scratch and chatter mark defects by Scanning Electronic Microscopy and for Removal rates of TEOS and SiN. The data normalized to the pads comprising the formulation of Comparative 1 are found in Table 4 shows a significant improvement in defect for the inventive formulations and an improvement in SiN Removal Rates with little to no decrease in TEOS removal rate.

TABLE 2
Test Set 1

| | Scratch and Chattermark defects |
|---|---|
| Formulation | normalized to Comparative 1 |
| Comparative 1 | 100% |
| Comparative 2 | 94% |
| Comparative 3 | 74% |
| Comparative 4 | 68% |
| Inventive 1 | 28% |

TABLE 3
Test Set 2

| | Scratch and | | SiN Removal |
|---|---|---|---|
| | Chattermark | | Rate |
| | defects | TEOS Removal | normalized |
| | normalized to | Rate normalized | to |
| Formulation | Comparative 1 | to Comparative 1 | Comparative 1 |
| Comparative 1 | 100% | 100% | 100% |
| Inventive 1 | 28% | 87% | 139% |
| Inventive 2 | 50% | 82% | 132% |

TABLE 4
Test set 3

| | | Scratch and | TEOS | SiN |
|---|---|---|---|---|
| | | Chattermark | Removal | Removal |
| | | defects | Rate | Rate |
| | | normalized | normalized | normalized |
| | | to | to | to |
| For- | | Comparative | Comparative | Comparative |
| mulation | Groove Pattern | 1 | 1 | 1 |
| Com- | Concentric with a | 100% | 100 | 100 |
| parative 1 | pitch 120 mil | | | |
| Inventive | Concentric, pitch | 34% | 95 | 123 |
| 1 | 120 mil with 32 | | | |
| | radial grooves | | | |
| Inventive | Concentric, pitch | 36% | 100 | 117 |
| 1 | 70 mil with 16 | | | |
| | radial grooves | | | |
| Inventive | Concentric, pitch | 18% | 93 | 108 |
| 3 | 120 mil with 32 | | | |
| | radial grooves | | | |
| Inventive | Concentric, pitch | 19% | 101 | 118 |
| 4 | 120 mil with 32 | | | |
| | radial grooves | | | |

Thus, disclosed herein are the following, non-limiting Aspects:

Aspect 1. A chemical mechanical polishing pad comprising a polishing layer having a polishing surface, wherein the polishing layer comprises a reaction product of an isocyanate terminated urethane prepolymer; and a curative system comprising (a) a sulfur containing diamine curative, and (b) a high molecular weight polyol curative, wherein the high molecular weight polyol curative has a number average molecular weight, MN, of 2,500 to 100,000; and wherein the high molecular weight polyol curative has an average of 3 to 10 hydroxyl groups per molecule; wherein the weight ratio of the high molecular weight polyol curative to the sulfur containing diamine curative is in the range of 3:10 to 7:10.

Aspect 2. The chemical mechanical polishing pad of Aspect 1 wherein the sulfur containing diamine curative comprises diamine functional aromatic compound having one or more alkylthio group pendant from an aromatic ring.

Aspect 3. The chemical mechanical polishing pad of Aspect 1 or 2 wherein the sulfur containing diamine curative comprises dialkylthiotoluenediamine, monoalkylthiotoluenediamine, or both, in each case where the alkyl group comprises 1, 2, or 3 carbon atoms.

Aspect 4. The chemical mechanical polishing pad of any one of the previous Aspects wherein the sulfur containing diamine curative comprises at least 95 weight percent based on total weight of the diamine curative of dimethylthiotoluenediamine.

Aspect 5. The chemical mechanical polishing pad of any one of the previous Aspects wherein the weight ratio of the high molecular weight polyol curative to the sulfur containing diamine is in the range of 4:10 to 5:10.

Aspect 6. The chemical mechanical polishing pad of any one of the previous Aspects wherein the isocyanate terminated urethane prepolymer has 8.3 to 9.8 wt % unreacted NCO groups.

Aspect 7. The chemical mechanical polishing pad of any one of the previous Aspects wherein the curative system has a plurality of reactive hydrogen groups and the isocyanate terminated urethane prepolymer has a plurality of unreacted NCO groups; and, wherein a stoichiometric ratio of the reactive hydrogen groups to the unreacted NCO groups is 0.85 to 1.15.

Aspect 8. The chemical mechanical polishing pad of any one of the previous Aspects wherein the polishing layer has a density of 0.7 to 1.1 g/cubic centimeter as determined by actual weight divided by its actual volume.

Aspect 9. The chemical mechanical polishing pad of any one of the previous Aspects wherein polishing layer comprises expanded polymeric microspheres.

Aspect 10. The chemical mechanical polishing pad of any one of the previous Aspects wherein polishing surface comprises a groove in a pattern of concentric circles, radial, or a combination thereof.

Aspect 11. The chemical mechanical polishing pad of any one of the previous Aspects wherein the high molecular weight polyol curative has a number average molecular weight of 5,000 to 50,000, preferably 7,500 to 25,000; or, more preferably, 10,000 to 12,000.

Aspect 12. The chemical mechanical polishing pad of any one of the previous Aspects wherein the high molecular weight polyol curative has an average of four to eight, preferably five to seven, or more preferably six hydroxyl groups per molecule.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). Moreover, stated upper and lower limits can be combined to form ranges (e.g., “at least 1 or at least 2 weight percent” and “up to 10 or 5 weight percent” can be combined as the ranges “1 to 10 weight percent”, or “1 to 5 weight percent” or “2 to 10 weight percent” or “2 to 5 weight percent”).

The disclosure may alternately comprise, consist of, or consist essentially of, any appropriate components herein disclosed. The disclosure may additionally, or alternatively, be formulated so as to be devoid, or substantially free, of any components, materials, ingredients, adjuvants or species used in the prior art compositions or that are otherwise not necessary to the achievement of the function and/or objectives of the present disclosure.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

Unless specified to the contrary herein, all test standards are the most recent standard in effect as of the filing date of this application, or, if priority is claimed, the filing date of the earliest priority application in which the test standard appears.

What is claimed is:

1. A chemical mechanical polishing pad comprising a polishing layer having a polishing surface, wherein the polishing layer comprises a reaction product of an isocyanate terminated urethane prepolymer; and a curative system comprising
(a) a sulfur containing diamine curative, and
(b) a high molecular weight polyol curative, wherein the high molecular weight polyol curative has a number average molecular weight, Mn, of 2,500 to 100,000; and wherein the high molecular weight polyol curative has an average of 3 to 10 hydroxyl groups per molecule;
wherein the weight ratio of the high molecular weight polyol curative to the sulfur containing diamine curative is in the range of 3:10 to 7:10.

2. The chemical mechanical polishing pad of claim 1 wherein the sulfur containing diamine curative comprises diamine functional aromatic compound having one or more alkylthio group pendant from an aromatic ring.

3. The chemical mechanical polishing pad of claim 2 wherein the sulfur containing diamine curative comprises dialkylthiotoluenediamine, monoalkylthiotoluenediamine, or both, in each case where the alkyl group comprises 1, 2, or 3 carbon atoms.

4. The chemical mechanical polishing pad of claim 1 wherein the sulfur containing diamine curative comprises at least 95 weight percent based on total weight of the diamine curative of dimethylthiotoluenediamine.

5. The chemical mechanical polishing pad of claim 1 wherein the weight ratio of the high molecular weight polyol curative to the sulfur containing diamine is in the range of 4:10 to 5:10.

6. The chemical mechanical polishing pad of claim 1 wherein the isocyanate terminated urethane prepolymer has 8.3 to 9.8 wt % unreacted NCO groups.

7. The chemical mechanical polishing pad of claim 1 wherein the curative system has a plurality of reactive hydrogen groups and the isocyanate terminated urethane prepolymer has a plurality of unreacted NCO groups; and, wherein a stoichiometric ratio of the reactive hydrogen groups to the unreacted NCO groups is 0.85 to 1.15.

8. The chemical mechanical polishing pad of claim 1 wherein the polishing layer has a density of 0.7 to 1.1 g/cubic centimeter as determined by actual weight divided by its actual volume.

9. The chemical mechanical polishing pad of claim 1 wherein polishing layer comprises expanded polymeric microspheres.

10. The chemical mechanical polishing pad of claim 1 wherein polishing surface comprises a groove in a pattern of concentric circles, radial, or a combination thereof.
